(19) United States
(12) Patent Application Publication
(10) Pub. No.: US 2026/0324102 A1
(43) Pub. Date: Oct. 15, 2026

(54) OPTOELECTRONIC SEMICONDUCTOR MODULE, DISPLAY DEVICE AND METHOD FOR MANUFACTURING AN OPTOELECTRONIC SEMICONDUCTOR MODULE

(71) Applicant: ams-OSRAM International GmbH, Regensburg (DE)

(72) Inventor: Rainer MINIXHOFER, Premstätten (AT)

(21) Appl. No.: 19/473,903

(22) PCT Filed: Mar. 12, 2024
(86) PCT No.: PCT/EP2024/056530

§ 371 Date: Oct. 9, 2025

(30) Foreign Application Priority Data
Apr. 12, 2023 (DE) 10 2023 109 174.3

(51) Int. Cl. H10F 39/10; H01S 5/026; H10F 77/00; H10F 77/124; H10F 77/40; H10F 77/50; H10H 20/819; H10H 29/14

(52) U.S. Cl. CPC H10F 39/103; H01S 5/0261; H01S 5/0262; H10F 77/124; H10F 77/413; H10F 77/50; H10F 77/953; H10H 20/819; H10H 29/14

(57) ABSTRACT

An optoelectronic semiconductor module includes a carrier, at least one emitter, and a detector is described herein. The carrier includes a control circuit region and a dielectric region arranged above the control circuit region. The dielectric region includes a plurality of cavities. The emitter and the detector are each arranged in a respective cavity and outside the control circuit region. The emitter and the detector share at least one common plane which is located within the dielectric region and oriented parallel to a main plane of extension of the carrier.

The present application relates to an optoelectronic semiconductor module, a display device and a method for manufacturing an optoelectronic semiconductor module. In particular, the optoelectronic module is configured to emit and/or detect electromagnetic radiation, for example light that is perceptible to the human eye.

It is an object of the present disclosure to provide an optoelectronic semiconductor module having improved optical characteristics and a reduced lateral extension.

A further object is to provide a display device with improved optical characteristics and a high resolution.

A further object is to provide a method for manufacturing an optoelectronic semiconductor module having improved optical characteristics.

These objects are achieved by devices and a method according to the independent patent claims. Advantageous embodiments and further developments of the devices and the method are the subject of the dependent patent claims and are furthermore apparent from the following description and the figures.

According to at least one embodiment the optoelectronic semiconductor module comprises a carrier, at least one emitter, and a detector. The carrier is preferably mechanically stable und self-supporting.

The emitter is for example configured to emit an electromagnetic radiation in a main emission direction during intended operation. The main emission direction is preferably oriented perpendicular to a main plane of extension of the optoelectronic semiconductor module. In particular, the emitter is configured to emit an electromagnetic radiation having a main wavelength in the spectral region visible to the human eye, i.e. between 380 nm and 750 nm. A main wavelength is to be understood as a wavelength in an emission spectrum where the intensity reaches a global maximum.

The detector is preferably configured to detect electromagnetic radiation in the infrared spectral range during intended operation. In particular, the detector is intended to detect an electromagnetic radiation having a wavelength in the region between 1 μm and 15 μm.

According to at least one embodiment of the optoelectronic semiconductor module, the carrier comprises a control circuit region and a dielectric region arranged above the control circuit region. Particularly, the control circuit region comprises a semiconductor material. Preferably, the control circuit region has a sufficient electrical conductivity at room temperature. For example, the control circuit region is formed with at least one of the following materials: silicon, germanium, gallium arsenide or silicon-germanium. The control circuit region preferably has a thickness between 10 μm and 750 μm. Here and in the following, a thickness is to be understood as an extension in a vertical direction. The vertical direction is oriented transverse, in particular perpendicular to a lateral direction. In particular, the control circuit region is embedded in the carrier. The control circuit region comprises a plurality of integrated circuits, for example digital circuits. Preferably, the control circuit region is intended to drive the emitter of the optoelectronic semiconductor module by using a pulse width modulation.

The dielectric region is preferably formed with at least one of the following materials: silicon dioxide, silicon nitride, low-k dielectrics, like organosilicate glass, porous silicon dioxide, carbon-doped oxide or spin-on polymeric dielectrics. The dielectric region particularly comprises leads and interconnect layers embedded in an electrically insulating material. In particular, a thickness of the dielectric region depends on a number of interconnect layers of the control circuit region. For example, the thickness of the dielectric region is between 0.5 μm and 2 μm for each interconnect layer, (i.e. the thickness of the dielectric region is between 3 μm and 12 μm for an interconnect stack having six layers). Additionally, a cavity can be introduced into the dielectric region. In order to enable the formation of the cavity, the thickness of the dielectric region is preferably increased by 3 μm to 10 μm. In summary, the dielectric region preferably has a thickness of at least 6 μm and at most 22 μm. The emitter and the detector are for example each arranged in a respective cavity of the dielectric region.

According to at least one embodiment of the optoelectronic semiconductor module, the emitter and the detector are arranged outside the control circuit region. The emitter and the detector are preferably manufactured using different structural sizes and different semiconductor materials and thus a different manufacturing process compared to the control circuit region. An arrangement of the emitter and the detector outside the control circuit region enables the use of particularly suitable manufacturing processes for the emitter, the detector and the control circuit region.

According to at least one embodiment of the optoelectronic semiconductor module, the emitter and the detector share at least one common plane, which is located within the dielectric region and oriented parallel to a main plane of extension of the carrier.

According to at least one embodiment, the optoelectronic semiconductor module comprises a carrier, at least one emitter, and a detector, wherein
the carrier comprises a control circuit region and a dielectric region arranged above the control circuit region,
the emitter and the detector are arranged outside the control circuit region,
the emitter and the detector share at least one common plane, which is located within the dielectric region and oriented parallel to a main plane of extension of the carrier.

An optoelectronic semiconductor module described herein is, inter alia, based on the following considerations: When manufacturing diodes that function as photodetectors, different structure sizes are advantageous than when manufacturing diodes that are used as digital switches due to physical constraints. To achieve higher sensitivity resulting in better detector performance, a diode with a larger area is advantageous, while a fast control circuit with a low latency preferably has a large number of diodes connected together via short leads in a small area. Thus, the integration of diodes used as high performance detectors together with diodes used in control circuits in one common manufacturing process, such as a complementary metal oxide semiconductor (short: CMOS) process, can lead to a trade-off between digital density and detector performance for each of these elements.

The optoelectronic semiconductor module described herein is, among other things, based on the idea of separating the manufacturing processes for the detector and the control circuit into different manufacturing processes. The control circuit can be formed by a CMOS process, creating a high density circuitry with small diodes, while the detector can for example be formed by a separate process using much larger area diodes having an advantageously high optical sensitivity.

According to at least one embodiment of the optoelectronic semiconductor module, the carrier is formed with silicon.

Silicon is an advantageously common semiconductor material and compatible with CMOS manufacturing processes.

According to at least one embodiment of the optoelectronic semiconductor module, the control circuit region is formed with silicon using a CMOS process.

According to at least one embodiment of the optoelectronic semiconductor module, the emitter is formed as a micro emitter. In particular, the emitter is a micro-LED. As a broad definition, a micro-LED could be seen as any light emitting diode (LED)—generally not a laser—with a particularly small size.

As a rule—and this is a very important criterion in addition to size—a growth substrate is removed from micro-LEDs, so that typical heights of such micro-LEDs are in the range of 1.5 μm to 10 μm, for example. In principle, a micro-LED does not necessarily have to have a rectangular radiation emission surface. Generally, for example, an LED could have a radiation emission surface in which, in plan view of the layers of the layer stack, any lateral extent of the radiation emission surface is less than or equal to 100 μm or less than or equal to 70 μm. For example, in the case of rectangular micro-LEDs, an edge length-especially in plan view of the layers of the layer stack-smaller than or equal to 70 μm or smaller than or equal to 50 μm is often cited as a criterion.

Mostly, such micro-LEDs are provided on wafers with-for the micro-LED non-destructively-detachable holding structures. At present, micro-LEDs are mainly used in displays. The micro-LEDs form pixels or subpixels and emit light of a defined color. Small pixel sizes and a high density with close distances make micro-LEDs suitable, among others, for small monolithic displays for AR applications, especially data glasses. In addition, other applications are being developed, in particular regarding the use in data communication or pixelated lighting applications.

Different ways of spelling micro-LED, e.g. μLED, μ-LED, uLED, u-LED or micro light emitting diode can be found in the relevant literature.

According to at least one embodiment of the optoelectronic semiconductor module, the emitter has an edge length of at most 50 μm, preferably of at most 20 μm and particularly preferably of at most 10 μm. The edge length corresponds to a lateral extension of the emitter. The lateral direction is oriented transverse, in particular perpendicular to a growth direction of the emitter. A small lateral extension enables a compact optoelectronic semiconductor module.

According to at least one embodiment of the optoelectronic semiconductor module, the emitter is formed as a laser component. In particular, the emitter is formed as a vertical cavity surface emitting laser (short: VCSEL), preferably a μVCSEL. A laser can emit electromagnetic radiation with a very high intensity and in a confined spatial region. A laser emitter is for example suitable for use in a projection device.

According to at least one embodiment of the optoelectronic semiconductor module, the semiconductor module has a first edge length of at most 60 μm and a second edge length of at most 30 μm. The first edge and the second edge are preferably arranged perpendicular to each other in a lateral plane. Advantageously, a small lateral extension enables a high density of a plurality of optoelectronic semiconductor modules, for example for use in a display device.

According to at least one embodiment of the optoelectronic semiconductor module, the detector is formed with a material which is different from the material of the carrier. For example, if the carrier is formed with a material which is suitable for the formation of a plurality of integrated circuits, the carrier is advantageously formed with silicon. However, silicon is not necessarily the most suitable material for the formation of a photodetector, because of its limited spectral sensitivity. The formation of the detector from a different material than the carrier allows for a much greater freedom of design.

According to at least one embodiment of the optoelectronic semiconductor module, the detector is formed with a III/V compound semiconductor material. A III/V compound semiconductor material comprises at least one element from the third main group, such as B, Al, Ga, In, and one element from the fifth main group, such as N, P, As. In particular, the term “III/V compound semiconductor material” includes the group of binary, ternary or quaternary compounds containing at least one element from the third main group and at least one element from the fifth main group, for example nitride and phosphide compound semiconductors. Such a binary, ternary or quaternary compound may further comprise, for example, one or more dopants as well as additional constituents.

A detector which is formed with a III/V compound semiconductor material can have a particularly high sensitivity in the infrared spectral range.

According to at least one embodiment of the optoelectronic semiconductor module, the detector comprises a detecting region and a detector circuit region. In particular, the detecting region comprises at least one photodiode to detect electromagnetic radiation. The detecting circuit region comprises an integrated circuit configured to evaluate a detector signal from the detecting region.

According to at least one embodiment of the optoelectronic semiconductor module, the detector is backside-illuminated.

In particular, the detector circuit region is arranged on the side of the detector facing towards the carrier. Thus, electromagnetic radiation can impinge on the detecting region without having to pass the detector circuit elements.

Advantageously, the detector comprises all its electrical contacts on a side facing towards the carrier. This enables an advantageously easy way to electrically connect the detector. Moreover, the lateral extension of the optoelectronic semiconductor module can advantageously be decreased.

According to at least one embodiment of the optoelectronic semiconductor module, the detector circuit region comprises an analog circuitry. The analog circuitry is preferably designed to convert a charge signal into a current signal.

According to at least one embodiment of the optoelectronic semiconductor module, the control circuit region is formed as a high-density CMOS circuit. In particular, a high-density CMOS circuit is manufactured in a 65-nm-process. For example, a 65-nm-process comprises transistors with a gate length of at most 50 nm. Preferably, the control circuit region is manufactured in a 22-nm-process and particularly preferably the control circuit region is manufactured in a 7-nm-process. Smaller structures enable the manufacturing of a control circuit region having a higher switching frequency and lower latencies. This can contribute to a control circuit which generates a pulse width modulation with an advantageously high frequency.

According to at least one embodiment of the optoelectronic semiconductor module, the optoelectronic semiconductor module comprises a through-connection extending through the control circuit region from a side opposite the dielectric region. In particular, the through-connection is a through-silicon via (short: TSV). Preferably, the through-connection is a vertical electrical connection that passes completely through the control circuit. For example, by means of the through-connection the optoelectronic semiconductor module can be electrically contacted by a backside only. Advantageously, this can lead to a smaller lateral extension and facilitate the electrical connection of the optoelectronic semiconductor module. Furthermore, wire bonds can be omitted.

According to at least one embodiment of the optoelectronic semiconductor module, an optical filter element is arranged upstream of the detector. In particular, electromagnetic radiation passes through the filter element before reaching the detector. The optical filter element is for example formed by at least one interference filter. Environmental disturbances can be blocked by means of the filter element.

According to at least one embodiment of the optoelectronic semiconductor module, the optical filter element is at least partially embedded in a cover element arranged on the dielectric region. In particular, the cover element is arranged on a side of the carrier opposite the control circuit region. The cover element is preferably formed with a dielectric material.

According to at least one embodiment of the optoelectronic semiconductor module, the optoelectronic semiconductor module comprises a plurality of emitters. The optoelectronic semiconductor module comprises preferably at least three emitters, particularly preferably at least 10 emitters. In particular, each emitter is intended to emit radiation of a different main wavelength. For example, a first emitter is intended to emit radiation of a red color, a second emitter is intended to emit radiation of a green color, and a third emitter is intended to emit radiation of a blue color in its intended operation. Such a red, green, blue (short: RGB) arrangement is especially suitable for a pixel of a display device.

A display device is also disclosed. According to at least one embodiment the display device comprises a plurality of optoelectronic semiconductor modules according to one of the preceding embodiments described herein.

A method for manufacturing an optoelectronic semiconductor module is also disclosed. The method for manufacturing an optoelectronic semiconductor module is particularly suitable for manufacturing an optoelectronic semiconductor module described herein. This means that all features disclosed in connection with the optoelectronic semiconductor module are also disclosed for the method for manufacturing an optoelectronic semiconductor module and vice versa.

According to at least one embodiment of the method for manufacturing an optoelectronic semiconductor module, a carrier having a control circuit region and a dielectric region arranged above the control circuit region is provided.

According to at least one embodiment of the method for manufacturing an optoelectronic semiconductor module, a plurality of cavities is introduced in the dielectric region.

According to at least one embodiment of the method for manufacturing an optoelectronic semiconductor module, an emitter and a detector are arranged in one cavity each.

According to at least one embodiment the method for manufacturing an optoelectronic semiconductor module comprises the following steps:
providing a carrier having a control circuit region and a dielectric region arranged above the control circuit region,
introducing a plurality of cavities in the dielectric region,
arranging an emitter and a detector in one cavity each.

An optoelectronic semiconductor module described herein is particularly suitable for use in proximity sensors, display management sensors or biosensors, for example as brightness adjustment sensors or fingerprint sensors in smartphones.

Further advantages and advantageous designs and further developments of the optoelectronic semiconductor module will become apparent from the following exemplary embodiments, which are described below in association with the figures.

In the figures:

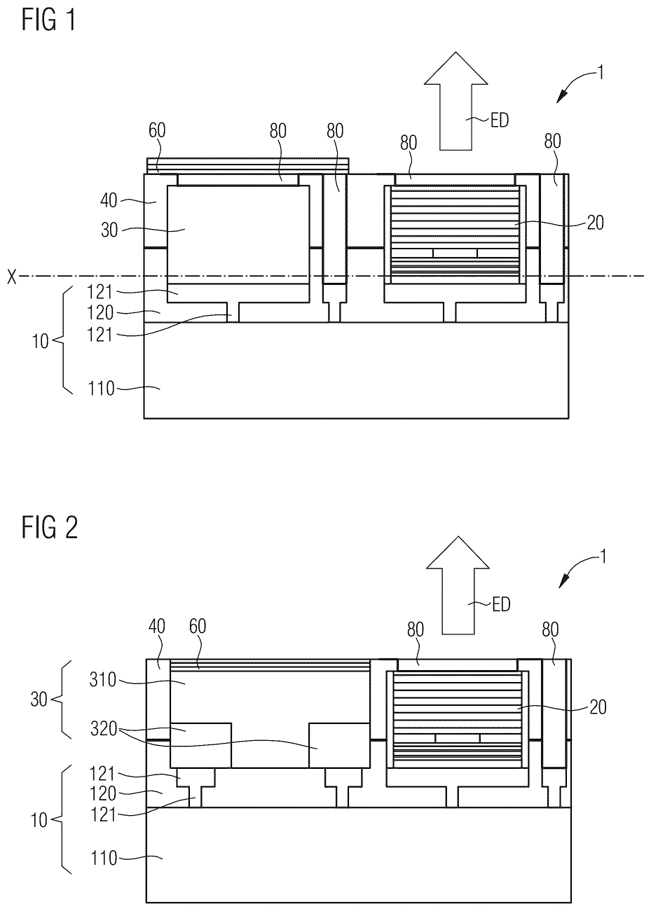

FIG. 1 shows a schematic cross-sectional view of an optoelectronic semiconductor module described herein according to a first exemplary embodiment,

FIG. 2 shows a schematic cross-sectional view of an optoelectronic semiconductor module described herein according to a second exemplary embodiment,

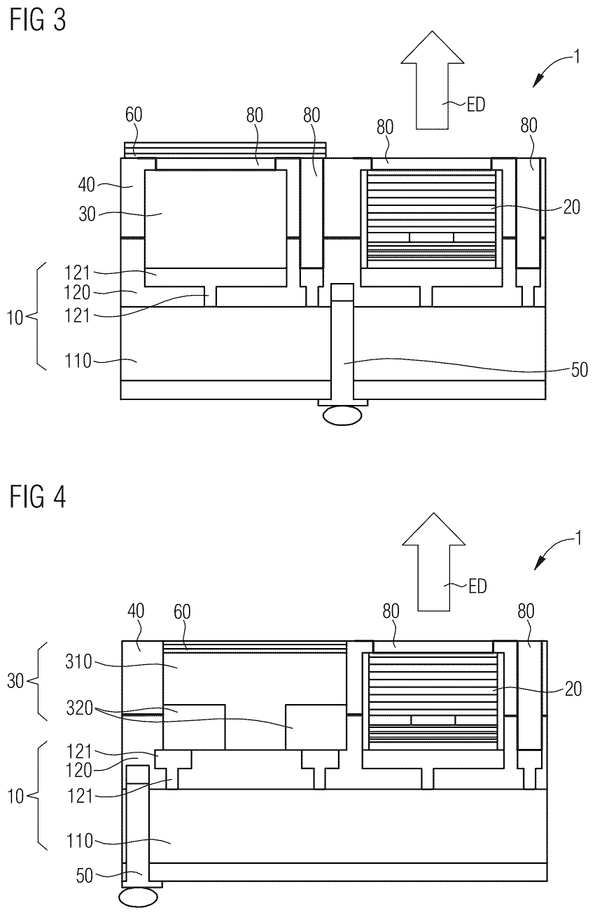

FIG. 3 shows a schematic cross-sectional view of an optoelectronic semiconductor module described herein according to a third exemplary embodiment,

FIG. 4 shows a schematic cross-sectional view of an optoelectronic semiconductor module described herein according to a fourth exemplary embodiment,

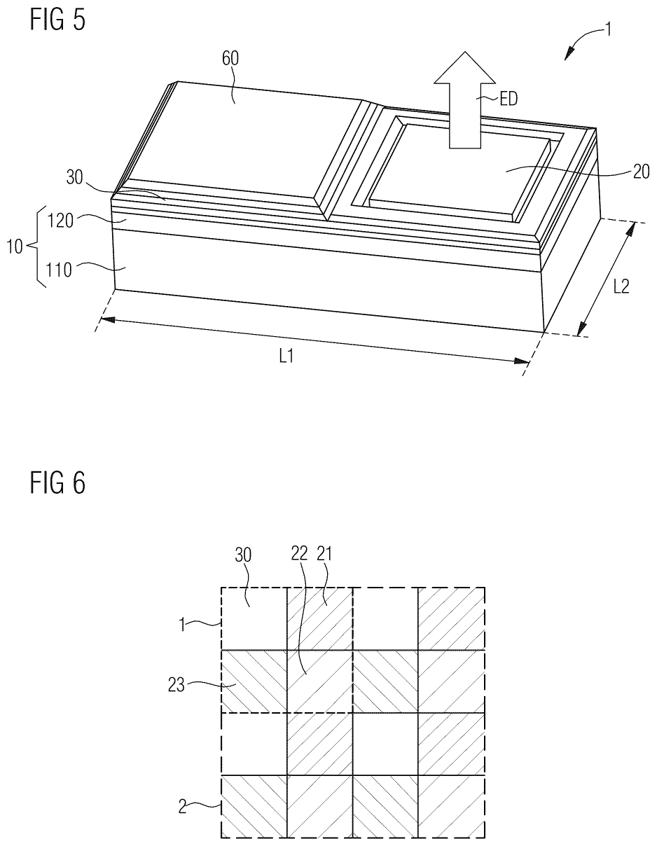

FIG. 5 shows a schematic perspective view of an optoelectronic semiconductor module described herein according to a fifth exemplary embodiment,

FIG. 6 shows a schematic top view of a display device described herein according to a first exemplary embodiment, and

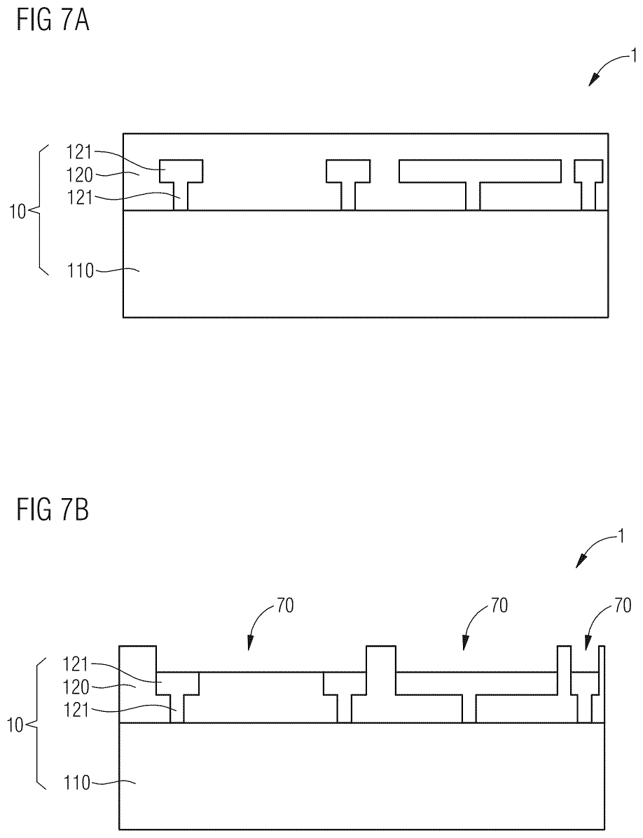

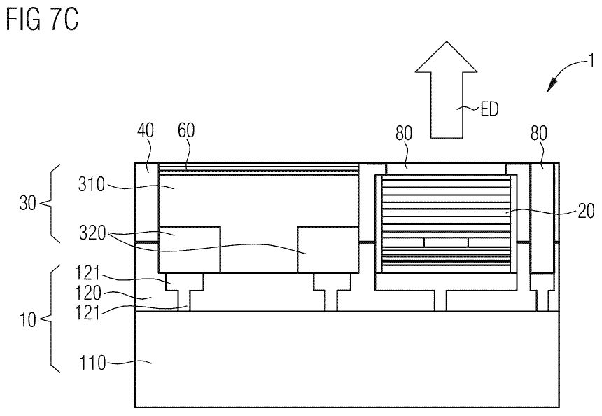

FIGS. 7A to 7C show schematic cross-sectional views of an optoelectronic semiconductor module in different steps of a method for its manufacture.

Identical, similar or equivalent elements are marked with the same reference signs in the figures. The figures and the proportions of the elements represented in the figures among each other are not to be considered as true to scale. Rather, individual elements may be oversized for better representability and/or comprehensibility.

FIG. 1 shows a schematic cross-sectional view of an optoelectronic semiconductor module 1 described herein according to a first exemplary embodiment. The optoelectronic semiconductor module 1 comprises a carrier 10, at least one emitter 20, and a detector 30.

The carrier 10 is preferably mechanically stable und self-supporting. The carrier 10 is formed with silicon. Silicon is an advantageously common semiconductor material and compatible with CMOS manufacturing processes. The carrier 10 comprises a control circuit region 110 and a dielectric region 120 arranged above the control circuit region 110. In particular, the control circuit region 110 is embedded in the carrier 10. The control circuit region 110 comprises a plurality of integrated circuits, for example digital circuits. The control circuit 110 can further comprise a plurality of analog circuits. The analog circuits are for example designed to convert a charge signal from the detector 30 to a current signal.

Preferably, the control circuit region 110 is configured to drive the emitter 20 of the optoelectronic semiconductor module 1 by using a pulse width modulation. The dielectric region 120 particularly comprises leads embedded in an electrically insulating material. The emitter 20 and the detector 30 are for example each arranged in a respective cavity 70 of the dielectric region 120. The dielectric region 120 is preferably formed with at least one of the following materials: silicon dioxide, silicon nitride, low-k dielectrics, like organosilicate glass, porous silicon dioxide, carbon-doped oxide or spin-on polymeric dielectrics. The dielectric region 120 comprises leads and interconnect layers 121 embedded in an electrically insulating material. In particular, a thickness of the dielectric region 120 depends on a number of interconnect layers 121 of the control circuit region 110. For example, the thickness of the dielectric region 120 is between 0.5 μm and 2 μm for each interconnect layer 121, (i.e. the thickness of the dielectric region is between 3 μm and 12 μm for an interconnect stack having six layers). The embodiment of FIG. 1 shows two interconnect layers 121.

The emitter 20 is configured to emit an electromagnetic radiation in a main emission direction ED during intended operation. In particular, the emitter 20 is configured to emit an electromagnetic radiation having a main wavelength in the spectral region visible to the human eye, i.e. between 380 nm and 750 nm. A main wavelength is to be understood as a wavelength in an emission spectrum where the intensity reaches a global maximum.

The detector 30 is preferably configured to detect electromagnetic radiation in the infrared spectral range during intended operation. In particular, the detector 30 is intended to detect an electromagnetic radiation having a wavelength in the region between 1 μm and 15 μm.

The emitter 20 and the detector 30 are arranged outside the control circuit region 110. The emitter 20 and the detector 30 are preferably manufactured using different structural sizes and different semiconductor materials compared to the control circuit region 110 and thus a different manufacturing process compared to the control circuit region 110. An arrangement of the emitter 20 and the detector 30 outside the control circuit region 110 enables the use of particularly suitable manufacturing processes for the emitter 20, the detector 30 and the control circuit region 110.

The emitter 20 and the detector 30 share at least one common plane X, which is located within the dielectric region 120 and oriented parallel to a main plane of extension of the carrier 10.

Upstream of the detector 30 element an optical filter element 60 is arranged. In particular, electromagnetic radiation passes through the optical filter element 60 first before reaching the detector 30. The optical filter element 60 is for example formed by at least one interference filter.

Advantageously, environmental disturbances can be blocked by means of the filter element 60.

The optical filter element 60 is at least partially embedded in a cover element 40. The cover element 40 is arranged on the dielectric region 120 of the carrier 10. In particular, the cover element 40 is arranged on a side of the carrier 10 opposite the control circuit region 110. The cover element 40 is formed with an electrically insulating material, for example silicon nitride or silicon oxide.

The emitter 20 and the detector 30 are electrically contacted via radiation-permeable contact structures 80. The contact structures 80 are arranged on a side of the detector 30 facing away from the carrier 10. The contact structures 80 are formed with an indium tin oxide (short: ITO). The contact structures 80 are radiation-permeable for electromagnetic radiation which is emitted by the emitter 20 during its intended operation and for electromagnetic radiation which is to be detected by the detector 30 during its intended operation.

FIG. 2 shows a schematic cross-sectional view of an optoelectronic semiconductor module 1 described herein according to a second exemplary embodiment. The optoelectronic semiconductor module 1 according to the second exemplary embodiment is essentially equal to the first exemplary embodiment shown in FIG. 1. In contrast to the first exemplary embodiment, the detector 30 is electrically connected via a backside only. The backside of the detector 30 is a side facing the carrier 10. In other words, the detector 30 comprises all its electrical contacts on a side facing towards the carrier 10. This enables an advantageously easy way to electrically connect the detector 30. Moreover, the lateral extension of the optoelectronic semiconductor module 1 is advantageously decreased.

The detector 30 further comprises a detecting region 310 and a detector circuit region 320. The detecting region 310 comprises at least one photodiode to detect an impinging electromagnetic radiation. The detector circuit region 320 comprises an integrated circuit configured to evaluate a detector signal from the detecting region 310.

Thus, the detector 30 according to the second exemplary embodiment is backside-illuminated. In particular, the detector circuit region 320 is arranged on the side of the detector 30 facing towards the carrier 10. Thus, electromagnetic radiation can impinge on the detecting region 310 without having to pass through the detector circuit region 320. The detector circuit region 320 preferably comprises an analog circuitry. The analog circuitry is preferably designed to convert a charge signal into a current signal.

The optical filter element 60 is at least partially embedded in the cover element 40 arranged on the dielectric region 120 of the carrier 10. In particular, the cover element 40 is arranged on a side of the carrier 10 opposite the control circuit region 110.

FIG. 3 shows a schematic cross-sectional view of an optoelectronic semiconductor module 1 described herein according to a third exemplary embodiment. The optoelectronic semiconductor module 1 according to the third exemplary embodiment is essentially equal to the first exemplary embodiment shown in FIG. 1. In addition to the first exemplary embodiment, the optoelectronic semiconductor module 1 comprises a through-connection 50 extending through the control circuit region 110 from a side opposite the dielectric region 120. By means of the through-connection 50 the optoelectronic semiconductor module 1 can advantageously be electrically contacted by a backside only. This can lead to a smaller lateral extension and facilitate the electrical connection of the optoelectronic semiconductor module 1. Furthermore, wire bonds can be omitted.

FIG. 4 shows a schematic cross-sectional view of an optoelectronic semiconductor module 1 described herein according to a fourth exemplary embodiment. The optoelectronic semiconductor module 1 according to the fourth exemplary embodiment is essentially equal to the second exemplary embodiment shown in FIG. 2. In addition to the second exemplary embodiment, the optoelectronic semiconductor module 1 comprises a through-connection 50 extending through the control circuit region 110 from a side opposite the dielectric region 120. By means of the through-connection 50 the optoelectronic semiconductor module 1 can advantageously be electrically contacted by a backside only. This can lead to a smaller lateral extension and facilitate the electrical connection of the optoelectronic semiconductor module 1. Furthermore, wire bonds can be omitted.

FIG. 5 shows a schematic perspective view of an optoelectronic semiconductor module 1 described herein according to a fifth exemplary embodiment. The optoelectronic semiconductor module 1 according to the fifth exemplary embodiment is essentially equal to the second exemplary embodiment shown in FIG. 2. The optoelectronic semiconductor module 1 comprises one emitter 20 and one detector 30 arranged adjacent to each other in a common plane X. In the lateral extension, the optoelectronic semiconductor module 1 has a first edge length L1 and a second edge length L2. The first edge length L1 is at most 35 μm, preferably at most 25 μm and particularly preferably at most 20 μm, the second edge length L2 is at most 70 μm, preferably at most 50 μm and particularly preferably at most 40 μm. The optoelectronic semiconductor module 1 is for example configured to be used as a proximity sensor, where the detector 30 is configured to detect reflections of an electromagnetic radiation which is emitted by the emitter 20 during its intended operation.

In an alternative arrangement, a plurality of optoelectronic semiconductor modules 1 according to the fifth exemplary embodiment can be combined in a multi-detector array. For example an array of 2×2 or 5×5 optoelectronic semiconductor modules 1 are combined in an array.

FIG. 6 shows a schematic top view of a display device 2 described herein according to a first exemplary embodiment. The display device 2 comprises a plurality of optoelectronic semiconductor modules 1 according to one of the preceding embodiments described herein. Each optoelectronic semiconductor module 1 comprises a plurality of emitters 20. In particular, the optoelectronic semiconductor module 1 has a first emitter 21, a second emitter 22 and a third emitter 23. The first emitter 21 is intended to emit radiation of a red color, the second emitter 22 is intended to emit radiation of a green color, and the third emitter 23 is intended to emit radiation of a blue color in its intended operation. Such a red, green, blue (short: RGB) arrangement is especially suitable for a pixel of a display device 2. In other words, every optoelectronic semiconductor module 1 constitutes one pixel of the display device 2. Advantageously, the optoelectronic semiconductor modules 1 are arranged in a so-called Bayer matrix to achieve a good color mixing.

FIGS. 7A to 7C show schematic cross-sectional views of an optoelectronic semiconductor module 1 in different steps of a method for its manufacture. FIG. 7A shows a first step, wherein a carrier 10 is provided. The carrier 10 comprises a control circuit region 110 and a dielectric region 120 arranged above the control circuit region 110.

FIG. 7B shows a further step of the method for manufacturing an optoelectronic semiconductor module 1. A plurality of cavities 70 is introduced into the carrier 10. The cavities 70 are introduced from a side opposite the control circuit region 110. The cavities 70 extend in the dielectric region 120 until they reach a metal layer.

Preferably, the cavities 70 do not extend into the control circuit region 110. In order to enable the formation of the cavity 70, the thickness of the dielectric region 120 is preferably increased by 3 μm to 10 μm. In summary, the dielectric region 120 preferably has a thickness of at least 6 μm and at most 22 μm.

FIG. 7C shows a further step of the method for manufacturing an optoelectronic semiconductor module 1. An emitter 20 and a detector 30 are arranged in one of the cavities 70 each. Furthermore, a cover element 40 is arranged on the dielectric region 120 of the carrier 10. In at least one cavity 70, an electrical contact structure 80 is arranged.

The invention described herein is not limited by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

This patent application claims the priority of the German patent application 102023109174.3, the disclosure content of which is hereby incorporated by reference.

### REFERENCES

1 optoelectronic semiconductor module
2 display device
10 carrier
20 emitter
21 first emitter
22 second emitter
23 third emitter
30 detector
40 cover element
50 through-connection
60 optical filter element
70 cavity
80 contact structure
110 control circuit region
120 dielectric region
121 interconnect layer
310 detecting region
320 detector circuit region
X common plane
ED main emission direction
L1 first edge length
L2 second edge length

1. An optoelectronic semiconductor module, comprising a carrier, at least one emitter, and a detector, wherein
the carrier comprises a control circuit region and a dielectric region arranged above the control circuit region,
the dielectric region comprises a plurality of cavities,
the emitter and the detector are each arranged in a respective cavity and outside the control circuit region,
the emitter and the detector share at least one common plane, which is located within the dielectric region and oriented parallel to a main plane of extension of the carrier.

2. The optoelectronic semiconductor module according to claim 1, wherein
the carrier is formed with silicon.

3. The optoelectronic semiconductor module according to claim 1, wherein
the emitter has an edge length of at most 50 μm, preferably of at most 20 μm and particularly preferably of at most 10 μm.

4. The optoelectronic semiconductor module according to claim 1, wherein
the emitter is formed as a laser component.

5. The optoelectronic semiconductor module according to claim 1, wherein
the semiconductor module has a first edge length of at most 60 μm and a second edge length of at most 30 μm.

6. The optoelectronic semiconductor module according to claim 1, wherein
the detector is formed with a material which is different from the material of the carrier.

7. The optoelectronic semiconductor module according claim 1, wherein
the detector is formed with a III/V compound semiconductor material.

8. The optoelectronic semiconductor module according to claim 1, wherein
the detector comprises a detecting region and a detector circuit region.

9. The optoelectronic semiconductor module according to claim 1, wherein
the detector is backside-illuminated.

10. The optoelectronic semiconductor module according to claim 9, wherein
the detector circuit region comprises an analog circuitry.

11. The optoelectronic semiconductor module according to claim 1, wherein
the control circuit region is formed as a high-density CMOS circuit.

12. The optoelectronic semiconductor module according to claim 1, wherein
the optoelectronic semiconductor module comprises a through-connection extending through the control circuit region from a side opposite the dielectric region.

13. The optoelectronic semiconductor module according to claim 1, wherein
an optical filter element is arranged upstream of the detector.

14. The optoelectronic semiconductor module according to claim 1, wherein
the optical filter element is at least partially embedded in a cover element arranged on the dielectric region.

15. The optoelectronic semiconductor module according to claim 1, wherein
the optoelectronic semiconductor module comprises a plurality of emitters.

16. The optoelectronic semiconductor module according to claim 1, wherein
the dielectric region is formed with at least one of the following materials: silicon dioxide, silicon nitride, low-k dielectrics, like organosilicate glass, porous silicon dioxide, carbon-doped oxide or spin-on polymeric dielectrics.

17. A display device, comprising a plurality of optoelectronic semiconductor modules according to claim 1.

18. A method for manufacturing an optoelectronic semiconductor module, comprising the following steps:
providing a carrier- having a control circuit region and a dielectric region arranged above the control circuit region,
introducing a plurality of cavities in the dielectric region,
arranging an emitter and a detector in one cavity each.
